(19) United States
(12) Patent Application Publication
(10) Pub. No.: US 2010/0276047 A1
(43) Pub. Date: Nov. 4, 2010

(54) WEAR RESISTANT COATING FOR INTERFACE OF WHEEL RIM AND TIRE

(75) Inventors: Richard M. Kleber, Clarkston, MI (US); Ravi Verma, Shelby Township, MI (US); Michael J. Lukitsch, Marysville, MI (US)

Correspondence Address: General Motors Corporation;c/o REISING ETHINGTON P.C., P.O. BOX 4390, TROY, MI, 48099-4390, US

(73) Assignee: GM GLOBAL TECHNOLOGY OPERATIONS, INC., DETROIT, MI (US)

(21) Appl. No.: 12/433,245

(22) Filed: Apr. 30, 2009

(51) Int. Cl. B60C 15/02; C23C 16/44

(52) U.S. Cl. 152/378 R; 427/248.1

(57) ABSTRACT

One exemplary embodiment of a wheel rim comprises magnesium. The wheel rim has one or more flange(s) that are constructed and arranged to seat a bead portion of a tire. One exemplary embodiment of a wear resistant coating is located over the flange on at least a part of a section of the flange(s) that opposes the bead portion of the tire.

### TECHNICAL FIELD

The technical field generally relates to wheel rims and tires, and to interfaces between wheel rims and tires.

### BACKGROUND

Automotive tire and wheel assemblies often include a tire mounted on a wheel rim. The tire commonly has a bead portion that forms an air-tight seal at an interface with a flange of the wheel rim. The tire also commonly has a chafer portion contacting the flange at the interface to help prevent chafing to the tire at the interface.

### SUMMARY OF EXEMPLARY EMBODIMENTS OF THE INVENTION

One exemplary embodiment includes a product which may include a wheel having a wheel rim, and may include a wear resistant coating. The wheel rim may comprise magnesium. The wheel rim may have one or more flange(s) that are constructed and arranged in order to seat a bead portion of an associated tire mounted to the wheel rim. The wear resistant coating may be located over the flange(s) on at least a part of a section of the flange(s) that opposes the bead portion of the tire when the tire is mounted to the wheel rim.

One exemplary embodiment includes a method which may include providing a wheel which may have a wheel rim that itself may comprise magnesium. The wheel rim may have a flange that is constructed and arranged in order to seat a bead portion of an associated tire when the tire is mounted to the wheel rim. The method may also include applying a wear resistant coating over the flange on at least a part of a section of the flange that opposes the bead portion of the tire when the tire is mounted to the wheel rim.

One exemplary embodiment includes a product which may include a tire, a wheel, and a wear resistant coating. The tire may have a first bead portion and a second bead portion. The wheel may have a wheel rim. The wheel rim may have a first flange and a second flange. The first flange may be constructed and arranged to seat the first bead portion, and the second flange may be constructed and arranged to seat the second bead portion. The wear resistant coating may be located at an interface between the first flange and the first bead portion, and between the second flange and the second bead portion.

Other exemplary embodiments of the invention will become apparent from the detailed description provided hereinafter. It should be understood that the detailed description and specific examples, while disclosing exemplary embodiments of the invention, are intended for purposes of illustration only and are not intended to limit the scope of the invention.

### BRIEF DESCRIPTION OF THE DRAWINGS

Exemplary embodiments of the invention will become more fully understood from the detailed description and the accompanying drawings, wherein:

FIG. 1 is a partial sectional view of an exemplary embodiment of a tire and wheel assembly.

FIG. 2 is an enlarged view taken at circle 2 in FIG. 1 of an exemplary embodiment of an interface of the tire and wheel assembly.

FIG. 3 is an enlarged view of an exemplary embodiment of a flange of the tire and wheel assembly of FIG. 1.

### DETAILED DESCRIPTION OF EXEMPLARY EMBODIMENTS

The following description of the embodiment(s) is merely exemplary (illustrative) in nature and is in no way intended to limit the invention, its application, or uses.

The figures illustrate an exemplary embodiment of a wear resistant coating 10 used with a tire and wheel assembly 12 of an associated automobile. The wear resistant coating 10 may help prevent abrasion, damage, and wear that may otherwise occur between the tire and wheel assembly 12 due to repeated vibration, rolling, sliding, and other movement. Though described in the context of an automobile, the wear resistant coating 10 may be used with tire and wheel assemblies of motor homes, trailers, semi-trailer trucks, and the like.

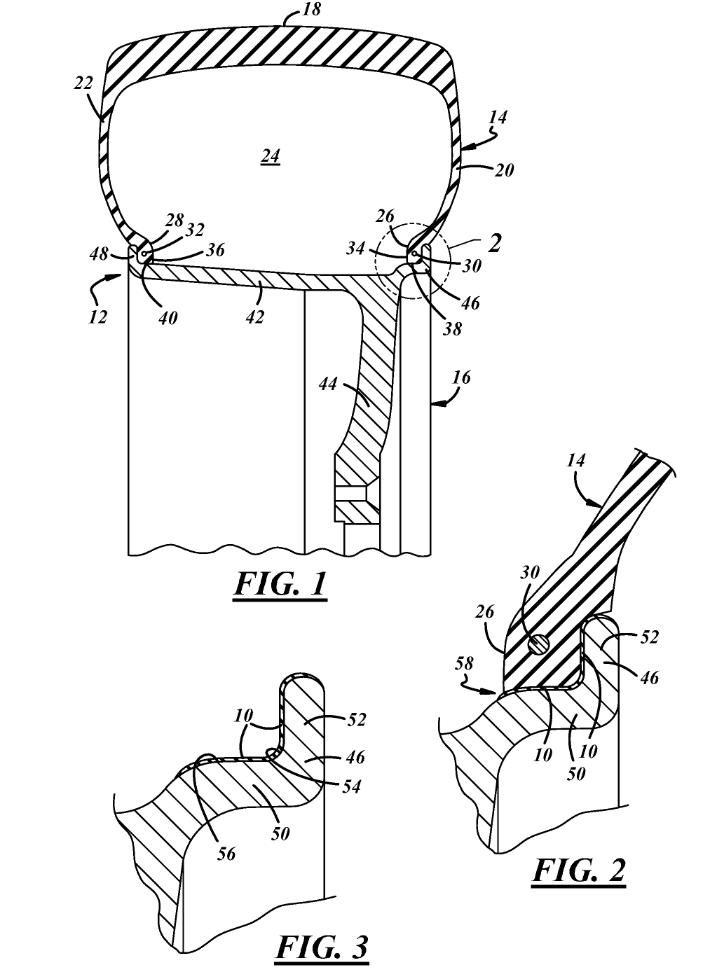

Referring to FIG. 1, the tire and wheel assembly 12 may include a tire 14 and a wheel 16. The tire 14 may mount to the wheel 16 and may come in direct contact with a road surface via a tread portion 18. The tire 14 may include a first and second side wall 20, 22 that, with the tread portion 18 and the wheel 16, may form a chamber 24 to hold pressurized gas. The tire 14 may have a first and second bead portion 26, 28 located at respective free ends of the first and second side walls 20, 22. The first and second bead portions 26, 28 may be constructed and arranged to seat against the wheel 16 and form an air-tight seal with the wheel 16. The first and second bead portions 26, 28 may extend circumferentially completely around the tire 14. In other embodiments, the first and second bead portions 26, 28 may have different constructions and arrangements.

Referring to FIGS. 1 and 2, the first bead portion 26 may include a first bead 30, and the second bead portion 28 may include a second bead 32. The first and second beads 30, 32 may stiffen the tire 14 at the respective bead portion to help hold the tire on the wheel 16. Each bead 30, 32 may include a bundle of steel wires embedded in the tire 14 at the respective bead portion. The tire 14 may also include a first and second chafer portion 34, 36 that may come into contact with the wheel 16 and may help prevent chafing to the tire thereat. The tire 14 may also have a first and second opposing surface 38, 40 that may face the wheel 16 when the tire is mounted thereon.

The wheel 16 may carry the tire 14 and may connect to other components of the associated automobile. The wheel 16 may have a wheel rim 42 and a wheel disc 44. The wheel rim 42 and the wheel disc 44 may be a one-piece structure, as shown, or may be separate pieces that are connected together. The wheel rim 42 may comprise magnesium, for example a magnesium alloy such as, but not limited to, AZ31 magnesium alloy, AZ60 magnesium alloy, AZ70 magnesium alloy, AZ80 magnesium alloy, AZ91 magnesium alloy, a ZK magnesium alloy, or an aluminum alloy. In the case of being one-piece, the wheel disc 44 may comprise magnesium, for example a magnesium alloy; and in the case of being separate pieces, the wheel disc 44 may comprise aluminum, for example an aluminum alloy.

The wheel rim 42 may have a first and second flange 46, 48 located at respective free ends of the wheel rim. The first and second flanges 46, 48 may complement the shape of the respective bead portions, and may be constructed and arranged to seat the respective bead portions. The first and second flanges 46, 48 may extend circumferentially continuously around the wheel rim 42. Referring to FIGS. 2 and 3, each of the first and second flanges 46, 48 may have an axial portion 50 and a radial portion 52 (named with respect to the circular shape of the wheel 16). Each of the first and second flanges 46, 48 may also have an opposing surface 54 that faces the tire 14 at the respective bead portion when the tire is mounted to the wheel 16. And each of the first and second flanges 46, 48 may have a bead seat 56 that supports the respective bead portion. In other embodiments, the first and second flanges 46, 48 may have different constructions and arrangements.

In some cases repeated vibrations, rolling, sliding, and other movement may cause abrasion, damage, and wear to the first and second flanges 46, 48 from the first and second bead portions 26, 28 at an interface 58 between the respective flanges and bead portions. The abrasion, damage, and wear may cause the tire 14 to lose inflation pressure over time. The wear resistant coating 10 may help prevent this abrasion, damage, and wear by, among other things, hardening the surfaces of the first and second flanges 46, 48, and in some cases by reducing friction between the first and second flanges and the first and second bead portions 26, 28.

Referring to FIGS. 2 and 3, the wear resistant coating 10 may be located between the respective bead portions 26, 28 and the flanges 46, 48, and may extend circumferentially completely therearound. In one embodiment, the wear resistant coating 10 is located over the full extent of the interface 58 between the respective bead portion and flange. In another embodiment, the wear resistant coating 10 may extend beyond the interface 58 and over the wheel rim 42 away from the respective flange. In another embodiment, the wear resistant coating 10 does not extend over the full extent of the interface 58, and instead only extends over a part of the interface such as only over the axial portion 50 or only over the radial portion 52. The remaining, or central portion, of the wheel rim 42 may not be coated with the wear resistant coating 10 as shown in FIGS. 2 and 3. In these examples and others, the wear resistant coating 10 is located on only a part of the respective flange that opposes the respective bead portion.

The wear resistant coating 10 may include a material that may harden the first and second flanges 46, 48 when applied thereto as compared to the first and second flanges without the wear resistant coating. In select embodiments, the wear resistant coating 10 may include titanium nitride, a ceramic, an oxide, a carbide, or a nitride. Other materials may be possible.

The exact application process of the wear resistant coating 10 may depend on, among other things, the material of the wear resistant coating, the structure of the wheel rim 42, and the material of the wheel rim. In select embodiments, the wear resistant coating 10 may be applied to the respective bead seat and on the respective opposing surface of the first and second flanges 46, 48 by a physical vapor deposition process, a chemical vapor deposition process, a plating process, a painting process, a direct current sputter process, a radio frequency sputter process, a laser ablation process, and a cathodic arc deposition process. Other application processes may be possible.

Depending on the material composition and application process of the wear resistant coating 10, in select embodiments the wear resistant coating may have a thickness in a range of about 1-5 microns or about 2-3 microns.

In use, the respective outer or opposing surfaces of the first and second bead portions 26, 28 may make direct contact with the wear resistant coating 10. The direct contact may help prevent abrasion, damage, and wear which may otherwise occur over time to the wheel rim 42 at the first and second flanges 46, 48. The wear resistant coating 10 may thus help keep the inflation pressure and prolong the useful life of the tire and wheel assembly 12.

One embodiment was evaluated by using what is known as a reciprocating wear test. In the evaluation, a first sample piece was placed in a tribotester, and a second and third sample piece were placed in the tribotester opposite the first sample piece. The first sample piece represented a bead portion of a tire; in this case the first sample piece was a 2 mm×2 mm bead portion of a Michelin® XW4® tire. The second sample piece represented a flange of a wheel rim including AZ31 magnesium alloy without a wear resistant coating. The third sample piece represented a flange of a wheel rim including AZ31 magnesium alloy with a wear resistant coating including titanium nitride. The wear resistant coating in the third sample piece was applied to the surface of the piece via a physical vapor deposition process, had a thickness of about 2 microns, and exhibited a hardness of about 23 GPa.

In the evaluation, the first sample piece was moved back-and-forth against the second sample piece and separately against the third sample piece. The first sample piece was moved back-and-forth with a load of about 10N in 6 mm strokes for about 1 million cycles for each of the second and third sample pieces. According to one estimate, these parameters simulate 500 miles of actual driving conditions.

An interferometer was then used to examine the wear tracks produced on the second and third sample pieces. In the second sample piece, the average wear amount (measured from the average unworn surface height) was about 1 micron. In the third sample piece, the average wear amount (measured from the average unworn surface height) was about 34 nanometers. Not all evaluations may produce the above results, and not all wear resistant coatings may produce the above results. Different evaluations including different tire samples, loads, cycles, stroke lengths, and the like may produce different results; and different material compositions, thicknesses, hardnesses, and the like may produce different results.

The above description of embodiments of the invention is merely exemplary in nature and, thus, variations thereof are not to be regarded as a departure from the spirit and scope of the invention.

What is claimed is:

1. A product comprising:
a wheel having a wheel rim comprising magnesium, the wheel rim having a at least one flange constructed and arranged to seat a bead portion of a tire; and
a wear resistant coating located over the at least one flange on at least a part of a section of the at least one flange opposing the bead portion of the tire.

2. A product as set forth in claim 1 wherein the at least one flange includes a first flange and a second flange, and the wear resistant coating is located over the first and second flanges on at least a part of a respective section of the first and second flanges opposing a respective bead portion of the tire.

3. A product as set forth in claim 1 wherein the wear resistant coating is located over the flange on the full extent of the section of the flange opposing the bead portion of the tire.

4. A product as set forth in claim 1 wherein the wear resistant coating is about 2 microns thick.

5. A product as set forth in claim 1 wherein the wear resistant coating comprises titanium nitride.

6. A product as set forth in claim 1 wherein the wear resistant coating comprises a ceramic.

7. A product as set forth in claim 1 wherein the wear resistant coating comprises an oxide.

8. A product as set forth in claim 1 wherein the wear resistant coating comprises a carbide.

9. A product as set forth in claim 1 wherein the wear resistant coating comprises a nitride.

10. A product as set forth in claim 1 further comprising the tire, the tire having the bead portion seated against the flange.

11. A method comprising:
providing a wheel having a wheel rim comprising magnesium, the wheel rim having a flange constructed and arranged to seat a bead portion of a tire; and
applying a wear resistant coating over the flange on at least a part of a section of the flange opposing the bead portion of the tire.

12. A method as set forth in claim 11 wherein applying the wear resistant coating comprises applying titanium nitride via a physical vapor deposition process.

13. A method as set forth in claim 11 wherein applying the wear resistant coating comprises applying the wear resistant coating over the full extent of the section of the flange opposing the bead portion of the tire.

14. A method as set forth in claim 11 wherein applying the wear resistant coating comprises applying the wear resistant coating to have a thickness of about 2 microns.

15. A product comprising:
a tire having a first bead portion and a second bead portion;
a wheel having a wheel rim, the wheel rim having a first flange and a second flange, the first and second flanges constructed and arranged to respectively seat the first and second bead portions of the tire; and
a wear resistant coating located at an interface between the first and second flanges and the respective first and second bead portions.

16. A product as set forth in claim 15 wherein the wear resistant coating comprises a nitride, a ceramic, an oxide, or a carbide.

17. A product as set forth in claim 15 wherein the wheel rim comprises magnesium.

18. A product as set forth in claim 15 wherein the wheel rim comprises aluminum.
